(19) United States
(12) Patent Application Publication
(10) Pub. No.: US 2007/0290372 A1
(43) Pub. Date: Dec. 20, 2007

(54) SEMICONDUCTOR DEVICE HAVING WIRE LOOP AND METHOD AND APPARATUS FOR MANUFACTURING THE SEMICONDUCTOR DEVICE

(75) Inventor: Won-Chul LIM, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/761,306

(22) Filed: Jun. 11, 2007

(30) Foreign Application Priority Data
Jun. 15, 2006 (KR) 2006-0053902

(51) Int. Cl. H01L 23/52

(52) U.S. Cl. 257/784

(57) ABSTRACT

A semiconductor device having a wire loop and a method and apparatus for manufacturing the semiconductor device are provided. The semiconductor device includes a wiring board having an electrode pad, a semiconductor chip having a bonding pad and attached on a top surface of the wiring board while exposing the electrode pad, and a wire loop electrically connecting the bonding pad of the semiconductor chip to the electrode pad of the wiring board. The wire loop includes a contact ball bonded on the bonding pad and a wire extending from a side portion of the contact ball and bonded on the electrode pad of the wiring board.

### CROSS-REFERENCE TO RELATED PATENT APPLICATION

This application claims priority under 35 USC § 119 to Korean Patent Application No. 10-2006-0053902, filed on Jun. 15, 2006, in the Korean Intellectual Property Office, the disclosure of which is incorporated herein in its entirety by reference.

### BACKGROUND

1. Technical Field

The present invention relates to a semiconductor device having a wire loop and a method and apparatus for manufacturing the semiconductor device.

2. Description of the Related Art

Generally, wire bonding is a process for electrically connecting a bonding pad of a semiconductor chip to a wiring board such as a lead frame or a printed circuit board using a wire.

Recently, ultrasonic thermo-compression type wire bonding using ultrasonic wave vibration has been introduced. A wire bonding process using the ultrasonic thermo-compression type wire bonding will now be described. First, a wire is inserted through a capillary disposed in a perpendicular direction with respect to a surface of the semiconductor chip and a contact ball is formed on an extreme end of the wire. Next, the capillary is moved such that the contact ball can be placed on the bonding pad and a predetermined force, ultrasonic wave vibration (or power), and heat are applied to the capillary to thermally-press the contact ball on the bonding pad of the semiconductor chip. In order to prevent the neck portion between the contact ball and the wire from breaking, the capillary is lifted by a predetermined height H1 and moved above an electrode of the wiring board. Then, the wire is thermally pressed and bonded on the wiring board and the wire is cut by applying a predetermined tension to the capillary.

In the course of lifting the capillary for preventing the neck portion from breaking, a kink height H1 is formed on the wire loop as shown in FIG. 1. Furthermore, since each of the contact ball 25 and the wire 27 has a predetermined diameter, the kink height H1 causes an overall height H2 of the wire loop 20 to increase. In FIG. 1, reference numerals 10, 15, and 16 denote a wire board, a semiconductor chip, and a bonding pad, respectively.

When the overall height of the wire loop increases, the stacking of layers of the semiconductor chip is limited. Furthermore, an overall thickness of the semiconductor package increases. Therefore, it is difficult to reduce the weight, thickness, length, and size of the semiconductor package.

To solve the above-described problems, Japanese unexamined Patent No. 2003-303844 discloses a method for horizontally moving the capillary that is disposed in a perpendicular direction to the surface of the semiconductor chip without lifting the capillary. However, when the capillary is moved without being lifted, the neck portion between the contact ball and the wire can easily break.

Therefore, there is a need for a method that can reduce the height of the wire loop without breaking the neck portion (a connecting portion) between the contact ball and the wire.

### SUMMARY

This disclosure provides a semiconductor device for which a height of a wire loop can be reduced without breaking a connecting portion between a contact ball and a wire and a method and apparatus for forming the wire loop on the semiconductor device.

In one embodiment, a semiconductor device comprises a wiring board having an electrode pad; a semiconductor chip having a bonding pad, wherein the semiconductor chip is attached on a top surface of the wiring board; and a wire loop electrically connecting the bonding pad of the semiconductor chip to the electrode pad of the wiring board. The wire loop includes a contact ball bonded on the bonding pad and a wire extending from a side portion of the contact ball and bonded on the electrode pad of the wiring board.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view of a semiconductor device having a conventional wire loop;

FIG. 2 is a sectional view of a semiconductor device having a wire loop according to an embodiment of the present invention;

FIGS. 3A through 3C are sectional views illustrating consecutive processes for manufacturing the semiconductor device of FIG. 2, according to an embodiment of the present invention; and

FIG. 4 is a schematic sectional view of an apparatus for manufacturing the semiconductor device of FIG. 2, according to an embodiment of the present invention.

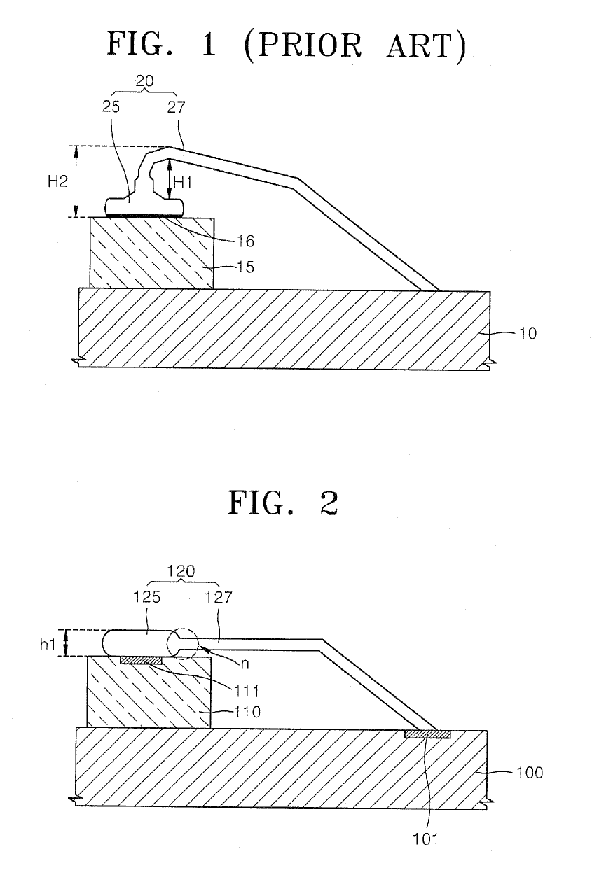

### DETAILED DESCRIPTION

Some embodiments of the present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their description will be omitted.

FIG. 2 is a sectional view of a semiconductor device having a wire loop according to an embodiment of the present invention.

Referring to FIG. 2, a semiconductor chip 110 is mounted on a wiring board 100 on which an electrode pad 101 is provided. A bonding pad 111 for supplying electric power to internal electrodes is formed on a top surface of the semiconductor chip 110. The bonding pad 111 of the semiconductor chip 110 and the electrode pad 101 of the wiring board 100 are electrically connected to each other by a wire loop 120.

The wire loop 120 includes a contact ball 125 bonded on the bonding pad 111 and a wire 127 extending from the bonding pad 111 and bonded on the electrode pad 101 of the wiring board 100. At this point, the contact ball 125 forms into a disk shape while being bonded on the bonding pad 111 due to applied pressure. The wire 127 extends from a side portion of the contact ball 125. That is, a neck portion (n) between the contact ball 125 and the wire 127 is positioned on the side portion of the contact ball 125.

Therefore, there is no kink height in the wire loop 120. That is, an overall height h1 of the wire loop is almost identical to a diameter of the contact ball 125. Therefore, the height of the wire loop can be considerably reduced as compared with that of the conventional wire loop.

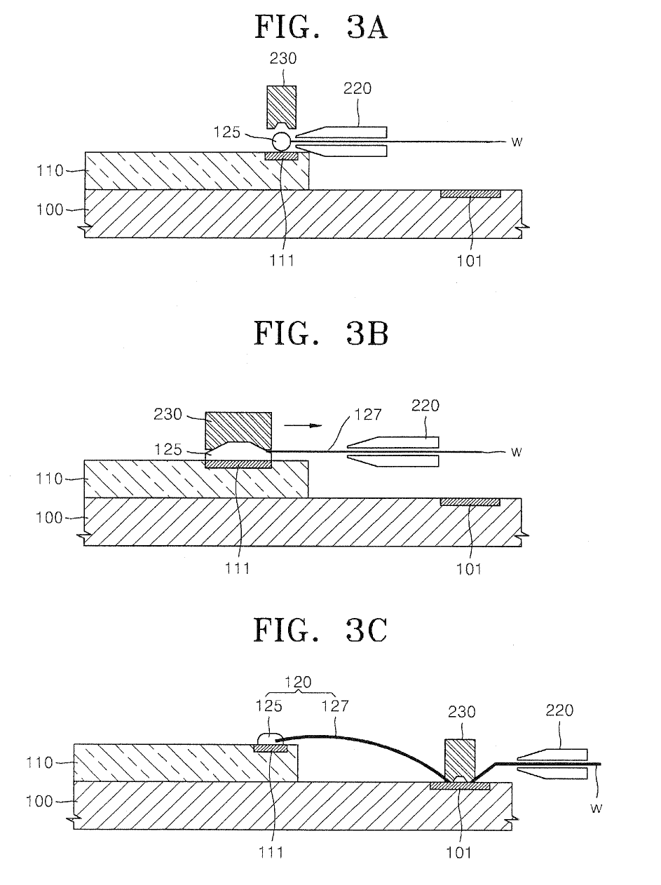

FIGS. 3A through 3C show consecutive processes for manufacturing the semiconductor device of FIG. 2, according to an embodiment of the present invention.

Referring first to FIG. 3A, a capillary 220 is disposed above the wiring board 100 on which the semiconductor chin 110 is mounted The capillary 220 is disposed such that a longitudinal axis thereof is parallel to surfaces of the semiconductor chip 110 and the wiring board 100. Therefore, a wire W penetrating the capillary 220 is also disposed parallel to the surfaces of the semiconductor chip 110 and the wiring board 100. The wire W penetrating the capillary 220 extends over an extreme end of the capillary 220. The extending portion of the wire W undergoes a spark discharge with a discharge electrode (not shown) to form the contact ball 125. Then, the capillary 220 is moved such that the contact ball 125 can be placed on the bonding pad 111 of the semiconductor chip 110. Here, reference numeral 101 denotes the electrode pad and reference numeral 230 indicates a pressing member for pressing the contact ball 125 on the bonding pad 111.

Referring to FIG. 3B, the contact ball 125 disposed on the bonding pad 111 is bonded on the bonding pad 111 using the pressing member 230. The pressing member 230 may be a capillary that may be disposed perpendicular to the capillary 220. The pressing member 230 including a portion normal to the top surface of the semiconductor chip 110 receives a force in the normal direction to press the contact ball 125 on the bonding pad 111, in the course of which an ultrasonic wave may be applied to improve the bonding efficiency. The application of heat and force to bond the contact ball 125 to the bonding pad 111 may be referred to as thermocompressing the contact ball 125. In this embodiment, in a state where a temperature of the semiconductor chip 110 is maintained at about 120-250° C., an electric power of 80-150 mA, a force of 15-30 g, and an ultrasonic wave vibration of 60,000-100,000 Hz is applied to perform the bonding process.

Once the contact ball 125 is bonded on the bonding pad 111, the capillary 220 is moved toward the electrode pad 101 of the wiring board 100. At this point, the longitudinal axis of the capillary 220 remains parallel to the semiconductor chip 110 and the wiring board 100. Therefore, the wire W, 127 extends from the side portion of the contact ball 125. In FIG. 3B, the arrow indicates a moving direction of the capillary.

The extension of the wire 127 from the side portion of the contact ball 125 is a feature of the present invention. That is, when the wire 127 extends from the side portion of the contact ball 125, the wire is not lifted. Therefore, there is no kink height in the wire loop and thus the overall height of the wire loop is almost identical to the diameter of the contact ball 125. As a result, the overall height of the wire loop can be reduced. Furthermore, since the capillary 220 is used to obtain the wire looping in a state where the longitudinal axis thereof is parallel to the surfaces of the semiconductor chip 110 and the wiring board 100, the wire 127 extends from the side portion of the contact ball 125, thereby preventing the wire from breaking.

As shown in FIG. 3C, after the capillary 220 passes over the electrode pad 101 of the wiring board 100, the wire near the extreme end of the capillary 220 is bonded on the electrode pad 101. Then, the ultrasonic wave is applied to the wire 127 and the electrode pad 101 through the pressing member 230 to thermal-bond the wire 127 and electrode pad 101 together. Then, the wire 127 is cut to finish the wire bonding.

Next, the discharge electrode momentarily contacts the wire W protruding from the extreme end of the capillary 220 to form the contact ball 125 on an extreme end of the wire. Then, the above-described wire bonding processes are repeated.

At this point, the diameter of the contact ball 125 may be adjusted by properly adjusting the contact time and supply voltage of the discharge electrode. Adjusting the contact time and supply voltage of the discharge electrode to adjust the diameter of the contact ball 125 may be referred to as a feedback operation. Since the diameter of the contact ball 125 determines the substantial height of the wire loop, the height of the wire loop can be properly adjusted considering the size of the package and the number of stacked layers of the die.

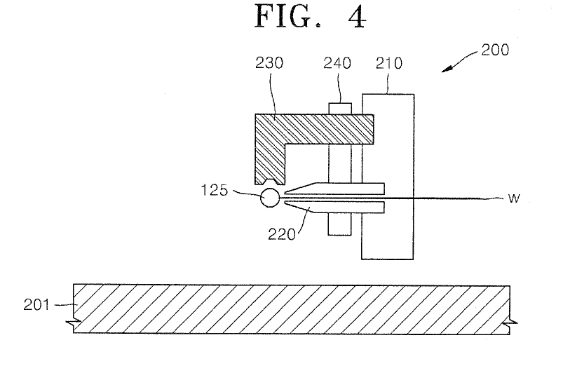

FIG. 4 is a sectional view of an apparatus for manufacturing the semiconductor device of FIG. 2, according to an embodiment of the present invention.

A wire loop forming apparatus 200 includes a bonding stage 201 and a bonding arm 210. The wiring board 100 on which the semiconductor chip 110 is mounted is disposed on the bonding stage 201 during the wire bonding process. Therefore, a surface of the bonding stage 201 is actually parallel to the surfaces of the semiconductor chip 110 and the wiring board 100. The bonding arm 210 is mechanically connected to the pressing member 230 and the capillary 220 to move the capillary 220 and the pressing member 230 in horizontal and vertical directions. The capillary 220 and the pressing member 230 are connected to a driving source such as a motor 240 to receive a driving force from the driving source.

At this point, it is important to install the capillary 220 on the bonding arm 210 such that the wire W is parallel to the surface of the bonding stage 201 (i.e., a surface of the semiconductor chip) along the longitudinal axis of the capillary. In addition, the pressing member 230 is provided to supply a pressure for bonding the contact ball 125 or the wire W to the semiconductor chip 110 or the wiring board 100. That is, the pressing member 230 is disposed at a predetermined angle with respect to the longitudinal axis of the capillary 220. The pressing member 230 may be installed such that an end portion thereof faces the extreme end of the capillary 220. The pressing member 230 may be disposed to be perpendicular to the longitudinal axis of the capillary 220. In addition, the wire loop forming apparatus 200 may further include a discharge electrode that forms the contact ball by melting an extreme end of the wire W protruding from the capillary 220. The discharge electrode is designed to move in the horizontal and vertical directions.

As described above, the longitudinal axis of the capillary 220 is disposed parallel to the surface of the bonding stage 210 to extend the wire from the side portion of the contact ball 125 and the pressing member 230 is provided to press the contact ball 125. As a result, the wire 127 can be extended without performing a wire lifting process, which has been conventionally performed to prevent the neck portion between the contact ball and the wire from breaking.

In this embodiment, the capillary 220 and the pressing member 230 are exemplary elements, and the present invention is not limited to them. Any devices that can move the wire W in a direction parallel to the bonding stage 201 can be applied to the present invention. In addition, any devices that can press the contact ball on the semiconductor chip or the wiring board while being connected to the bonding arm 200 can be applied to the present invention. The pressing member may be substantially similar to the capillary.

### TEST EXAMPLE

In order to test the apparatus described above, a contact ball 125 having a diameter of 25 μm was formed and a wire 127 was extended from the side portion of the contact ball 125. As a result, an overall height of a wire loop was 25-35 μm.

This shows that a height of the wire loop of the present invention is reduced by more than about 30% as compared with that (50-60 μm including kink height) of the conventional wire loop.

According to the present invention, the wire can be extended from the side portion of the contact ball without performing a wire lifting process, which has been conventionally performed to prevent the neck portion between the contact ball and the wire from breaking, and the kink height of the wire loop can be reduced. Therefore, the overall height of the wire loop can be reduced to be almost identical to a diameter of the contact ball. As a result, an overall thickness of the package can be reduced.

According to an aspect of the invention, there is provided a semiconductor device including: a wiring board having an electrode pad; a semiconductor chip having a bonding pad, wherein the semiconductor chip is attached on a top surface of the wiring board while exposing the electrode pad; and a wire loop electrically connecting the bonding pad of the semiconductor chip to the electrode pad of the wiring board, wherein the wire loop includes a contact ball bonded on the bonding pad and a wire extending from a side portion of the contact ball and bonded on the electrode pad of the wiring board.

A neck portion between the contact ball and the wire may be placed on a side surface of the contact ball, the side surface being perpendicular to a top surface of the semiconductor chip.

According to another aspect of the invention, there is provided a method of manufacturing a semiconductor device having a wire loop, including: forming a contact ball on an extreme end of a wire protruding from a capillary; locating the capillary such that the contact ball is disposed on a bonding pad of a semiconductor chip; bonding the contact ball on the bonding pad; horizontally moving the capillary such that the wire extends from a side portion of the contact ball; thermocompressing and bonding the wire on an electrode pad of a wiring board; and cutting the wire.

The wire may extend from the side portion of the contact ball in a state where the capillary is disposed such that a longitudinal axis of the capillary is parallel to a top surface of the semiconductor chip.

The bonding of the contact ball may be performed by applying an electric power of about 80-150 mA and a force of about 15-30 g in a state where a temperature of the semiconductor chip is maintained at about 120-250° C.

The bonding of the contact ball may be performed by further applying an ultrasonic wave vibration of about 60,000-100,000 Hz.

The thermally pressing and bonding of the wire may be preformed by applying an ultrasonic wave.

The method may further include performing a feedback operation to the forming of the contact ball after the cutting of the wire.

A height of the wire loop may be adjusted by adjusting a size of the contact ball formed on the extreme end of the wire.

According to still another aspect of the invention, there is provided an apparatus for manufacturing a semiconductor device, including: a bonding stage on which a semiconductor chip and a wiring board may be disposed; a capillary disposed above the bonding stage and supporting the wire such that the wire is parallel to a top surface of the bonding stage; a pressing member disposed at a predetermined angle with respect to the capillary; and a bonding arm connected to the capillary and the pressing member to move the capillary and the pressing member to a predetermined location.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor device comprising:
a wiring board having an electrode pad;
a semiconductor chip having a bonding pad, wherein the semiconductor chip is attached on a top surface of the wiring board; and
a wire loop electrically connecting the bonding pad of the semiconductor chip to the electrode pad of the wiring board,
wherein the wire loop includes a contact ball bonded on the bonding pad and a wire extending from a side portion of the contact ball and bonded on the electrode pad of the wiring board.

2. The semiconductor device of claim 1, wherein a neck portion of the wire loop between the contact ball and the wire is disposed on a side surface of the contact ball, the side surface being perpendicular to a top surface of the semiconductor chip.

3. A method of manufacturing a semiconductor device having a wire loop, comprising:
forming a contact ball on an end of a wire protruding from a capillary;
locating the capillary such that the contact ball is disposed on a bonding pad of a semiconductor chip;
bonding the contact ball on the bonding pad;
moving the capillary such that the wire extends from a side portion of the contact ball;
bonding the wire on an electrode pad of a wiring board; and
cutting the wire.

4. The method of claim 3, wherein the wire extends from the side portion of the contact ball and the capillary is disposed such that a longitudinal axis of the capillary is parallel to a top surface of the semiconductor chip.

5. The method of claim 3, wherein bonding the contact ball comprises applying an electric power of about 80-150 mA and a force of about 15-30 g while a temperature of the semiconductor chip is maintained at about 120-250° C.

6. The method of claim 5, wherein bonding the contact ball further comprises applying an ultrasonic wave vibration of about 60,000-100,000 Hz.

7. The method of claim 3, wherein bonding the wire comprises applying an ultrasonic wave.

8. The method of claim 3, further comprising performing a feedback operation during the forming of another contact ball after cutting the wire.

9. The method of claim 3, wherein a height of the wire loop is adjusted by adjusting a size of the contact ball formed on the end of the wire.

10. The method of claim 9, wherein forming the contact ball comprises contacting a discharge electrode to the end of the wire.

11. The method of claim 10, wherein adjusting the size of the contact ball comprises varying one or more of a contact time between the discharge electrode and the end of the wire and a supply voltage of the discharge electrode.

12. The method of claim 3, wherein bonding the wire comprises thermocompressing the wire.

13. An apparatus for manufacturing a semiconductor device, comprising:
a bonding stage;
a capillary disposed on the bonding stage and supporting a wire such that the wire is parallel to a top surface of the bonding stage;
a pressing member disposed at a predetermined angle with respect to the capillary; and
a bonding arm connected to the capillary and the pressing member, the bonding arm configured to move the capillary and the pressing member to a predetermined location.

14. The apparatus of claim 13, wherein the pressing member includes a portion perpendicular to a longitudinal axis of the capillary and facing an end of the capillary.

15. The apparatus of claim 13, wherein the capillary and the pressing member are connected to a driving source.

16. The apparatus of claim 15, wherein the driving source is configured to supply a driving force comprising an electric power of about 80 to about 150 mA and a force of about 15 to about 30 g.

17. The apparatus of claim 15, wherein the driving source is configured to supply an ultrasonic wave vibration of about 60 to about 100 KHz.

18. The apparatus of claim 13, wherein the bonding stage is configured to maintain a temperature of a semiconductor chip placed thereon at about 120 to about 125° C.

19. The apparatus of claim 13, wherein the pressing member is another capillary that is disposed perpendicular to the capillary.

20. The apparatus of claim 13, further comprising a discharge electrode configured to move in horizontal and vertical directions.
